(19) United States
(12) Patent Application Publication
(10) Pub. No.: US 2025/0054928 A1
(43) Pub. Date: Feb. 13, 2025

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventor: Jia Liu, Yokohama Kanagawa (JP)

(21) Appl. No.: 18/601,865

(22) Filed: Mar. 11, 2024

(30) Foreign Application Priority Data
Aug. 7, 2023 (JP) 2023-128355

(51) Int. Cl. H01L 25/16; H01L 25/075; H01L 27/12; H01L 33/62

(52) U.S. Cl. CPC H01L 25/167; H01L 25/0753; H01L 27/1244; H01L 33/62

(57) ABSTRACT

According to one embodiment, a semiconductor device includes a substrate; a first transistor and a second transistor having their sources commonly coupled to each other; a light emitting element having an anode electrode and a cathode electrode; a light receiving element turning on or off the first transistor and the second transistor depending on a light emission state of the light emitting element; a first filter element coupled to the anode electrode of the light emitting element; and a second filter element coupled to the cathode electrode of the light emitting element.

### CROSS-REFERENCE TO RELATED APPLICATIONS

This application is based upon and claims the benefit of priority from Japanese Patent Application No. 2023-128355, filed Aug. 7, 2023, the entire contents of which are incorporated herein by reference.

### FIELD

Embodiments described herein relate generally to a semiconductor device.

### BACKGROUND

A photo relay device including a light emitting element and a light receiving element is known as a semiconductor device. The photo relay device is a non-contact relay, and is used to transmit an AC signal and a DC signal.

### BRIEF DESCRIPTION OF THE DRAWINGS

FIG. 1 is a circuit diagram for illustrating an example of a circuit configuration of a semiconductor device according to an embodiment.

FIG. 2 is a perspective view showing an example of a structure of the semiconductor device according to the embodiment.

FIG. 3 is a plan view showing an example of a planar structure of the semiconductor device according to the embodiment.

FIG. 4 is a perspective view showing an example of a structure of a semiconductor device according to a first modification.

FIG. 5 is a perspective view showing an example of a structure of a semiconductor device according to a second modification.

FIG. 6 is a plan view showing an example of a planar structure of the semiconductor device according to the second modification.

FIG. 7 is a plan view showing an example of a planar structure of a semiconductor device according to a third modification.

FIG. 8 is a perspective view showing an example of a structure of a semiconductor device according to a fourth modification.

FIG. 9 is a plan view showing an example of a planar structure of the semiconductor device according to the fourth modification.

FIG. 10 is a plan view showing an example of a planar structure of a semiconductor device according to another example.

### DETAILED DESCRIPTION

In general, according to one embodiment, a semiconductor device includes a substrate; a first transistor and a second transistor provided above a first surface of the substrate and having their sources commonly coupled to each other; a light emitting element provided above the first surface of the substrate and having an anode electrode and a cathode electrode; a light receiving element provided above the first surface of the substrate and turning on or off the first transistor and the second transistor depending on a light emission state of the light emitting element; a first filter element provided above the first surface of the substrate and coupled to the anode electrode of the light emitting element; and a second filter element provided above the first surface of the substrate and coupled to the cathode electrode of the light emitting element.

An embodiment will be described below with reference to the drawings. In the following description, components having the same functions and configurations are denoted by common reference numerals. Respective dimensions and proportions in the drawings are not necessarily the same as actual ones.

### 1 Embodiment

A semiconductor device according to an embodiment will be described.

An example of the semiconductor device according to the embodiment is a photo relay device for transmitting an AC signal and a DC signal. An example of the semiconductor device according to the embodiment is a package of an electronic component. In the following description, the AC signal and the DC signal are also merely referred to as signals.

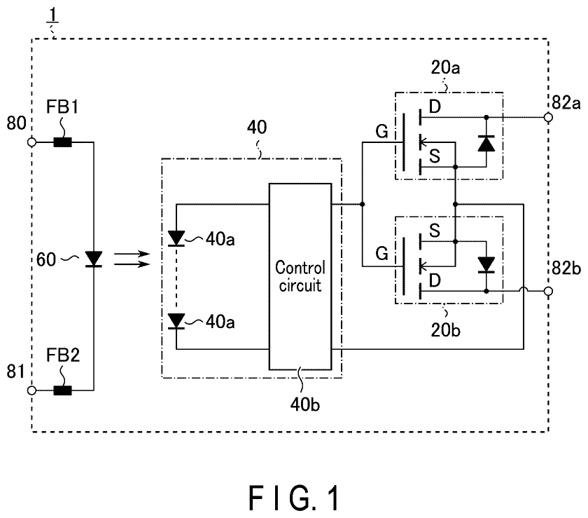

An example of a circuit configuration of the semiconductor device according to the embodiment will be described with reference to FIG. 1. FIG. 1 is a circuit diagram for illustrating an example of the circuit configuration of the semiconductor device according to the embodiment.

A semiconductor device 1 includes terminals 80, 81, 82a, and 82b. A voltage for driving the semiconductor device 1 is supplied to the terminals 80 and 81. While the semiconductor device 1 is driven, the semiconductor device 1 can transmit a signal via the terminals 82a and 82b.

The semiconductor device 1 further includes MOSFETS (metal-oxide-semiconductor field effect transistors) 20a and 20b, a light receiving element 40, a light emitting element 60, and ferrite beads (filter elements) FB1 and FB2. An example of the MOSFETs 20a and 20b is an enhancement-type N-channel MOSFET. An example of the light receiving element 40 is a sensor including a PDA (photo diode array) or a photo transistor. A case where the light receiving element 40 includes a PDA will be described below. An example of the light emitting element 60 is an LED (light emitting diode).

The light emitting element 60 is coupled to the terminals 80 and 81, respectively, via the ferrite beads FB1 and FB2. More specifically, an anode electrode of the light emitting element 60 is coupled to the terminal 80 via the ferrite bead FB1, for example. A cathode electrode of the light emitting element 60 is coupled to the terminal 81 via the ferrite bead FB2, for example. The light emitting element 60 is driven by power to be supplied to the terminals 80 and 81. As a result, a light emission state of the light emitting element 60 is an on-state (illuminating state) or an off-state (non-illuminating state).

The light receiving element 40 includes a plurality of photodiodes 40a coupled in series and a control circuit 40b, for example. The number of photodiodes 40a is several to several tens, for example. Both ends of the plurality of photodiodes 40a coupled in series are each coupled to the control circuit 40b. The control circuit 40b turns on the MOSFETs 20a and 20b using photovoltaic power generated by the plurality of photodiodes 40a.

The MOSFETS 20a and 20b have their respective gates commonly coupled to an anode electrode of the light receiving element 40. The MOSFETs 20a and 20b have their respective sources commonly coupled to a cathode electrode of the light receiving element 40. The MOSFET 20a has its drain coupled to the terminal 82a. The MOSFET 20b has its drain coupled to the terminal 82b.

When the light emitting element 60 changes from the off state to the on state in the above-described circuit configuration of the semiconductor device 1, light is emitted from the light emitting element 60. The light receiving element 40 changes the MOSFETs 20a and 20b from an off state to an on state using a voltage generated by a photovoltaic effect due to light from the light emitting element 60. As a result, the terminals 82a and 82b are electrically coupled to each other. Thus, the semiconductor device 1 transmits a signal to be supplied to one of the terminals 82a and 82b to the other terminal via the MOSFETs 20a and 20b.

When the light emitting element 60 changes from the on state to the off state, emission of light from the light emitting element 60 is stopped. As a result, the MOSFETs 20a and 20b change from the on state to the off state. Thus, the semiconductor device 1 electrically insulates the terminals 82a and 82b from each other.

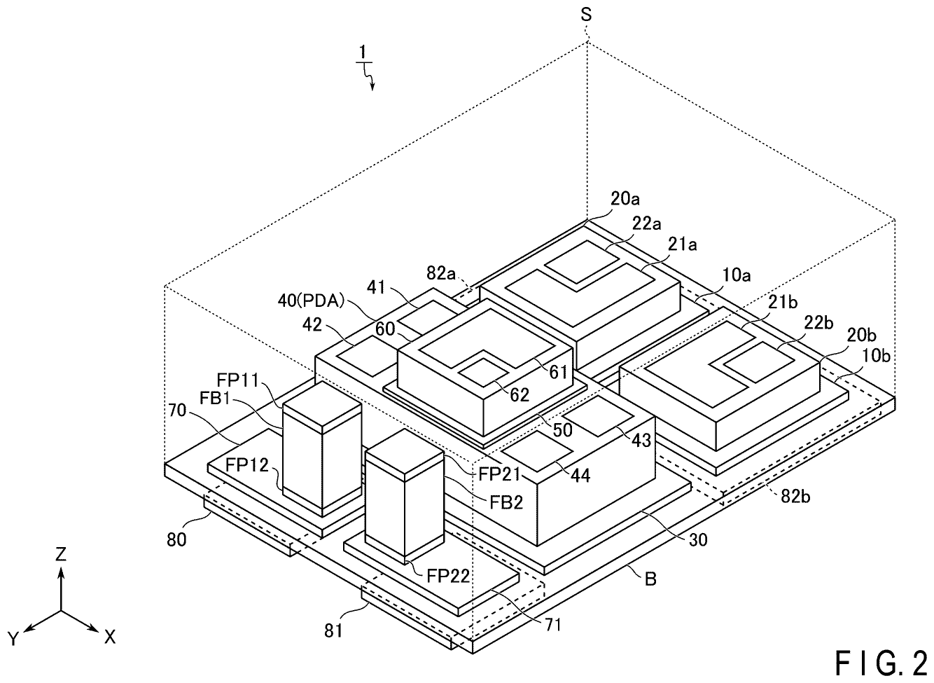

Then, a structure of the semiconductor device 1 according to the embodiment will be described with reference to FIG. 2. FIG. 2 is a perspective view showing an example of the structure of the semiconductor device according to the embodiment. In the following description, a Z-direction corresponds to a direction perpendicular to a surface of a substrate on which the semiconductor device 1 is formed. An X-direction is a direction parallel to the surface of the substrate. A Y-direction is a direction parallel to the surface of the substrate and perpendicular to the X-direction. In FIG. 2, illustration of wirings is omitted to facilitate understanding of the drawings. The wirings will be described below.

The semiconductor device 1 further includes a substrate B, electrodes (pads) 10a, 10b, 70, and 71, a support base 30, a bonding layer 50, and a sealing material S. In the following description, a side on which the MOSFET 20a out of the substrate B and the MOSFET 20a is provided is referred to as an upper side in the Z-direction. A side on which the substrate B out of the substrate B and the MOSFET 20a is provided is referred to as a lower side in the Z-direction.

Examples of the substrate B include a circuit board using BT (bismaleimide triazine) resin and a flexible printed circuit (FPC) using polyimide.

The electrodes 10a, 10b, 70, and 71 are provided on an upper surface of the substrate B. An example of the electrodes 10a, 10b, 70, and 71 is a metal foil containing copper. The electrodes 10a, 10b, 70, and 71 are provided such that the electrodes 10a and 10b and the electrodes 70 and 71 line up in the Y-direction, for example. In the following description, a side on which the electrodes 10a and 10b among the electrodes 10a, 10b, 70, and 71 are provided is referred to as one end side in the Y-direction. A side on which the electrodes 70 and 71 among the electrodes 10a, 10b, 70, and 71 are provided is referred to as the other end side in the Y-direction. The electrodes 10a and 10b are provided to line up in the X-direction, for example. In the following description, a side on which the electrode 10a out of the electrodes 10a and 10b is provided is referred to as one end side in the X-direction. A side on which the electrode 10b out of the electrodes 10a and 10b is provided is referred to as the other end side in the X-direction. The electrodes 70 and 71 are provided to line up in the X-direction, for example. The electrode 70 is provided on the one end side in the X-direction with respect to the electrode 71, for example. The electrodes 70 and 71 are preferably provided at positions close to each other in the X-direction.

The MOSFET 20a includes electrodes 21a and 22a and an electrode, not illustrated in FIG. 2, arranged in a lower portion of the MOSFET 20a. The electrodes 21a and 22a are arranged on an upper surface of the MOSFET 20a. The electrode arranged in the lower portion of the MOSFET 20a contacts the electrode 10a via a conductive paste or the like on a lower surface of the MOSFET 20a, for example. The electrode arranged in the lower portion of the MOSFET 20a can have a similar size to that of the lower surface of the MOSFET 20a, for example. The electrode 21a functions as a source electrode of the MOSFET 20a. The electrode 22a functions as a gate electrode of the MOSFET 20a. The electrode arranged in the lower portion of the MOSFET 20a functions as a drain electrode of the MOSFET 20a.

The MOSFET 20b includes electrodes 21b and 22b and an electrode, not illustrated in FIG. 2, arranged in a lower portion of the MOSFET 20b. The electrodes 21b and 22b are arranged on an upper surface of the MOSFET 20b. The electrode arranged in the lower portion of the MOSFET 20b contacts the electrode 10b via a conductive paste or the like on a lower surface of the MOSFET 20b. The electrode arranged in the lower portion of the MOSFET 20b can have a similar size to that of the lower surface of the MOSFET 20b, for example. The electrode 21b functions as a source electrode of the MOSFET 20b. The electrode 22b functions as a gate electrode of the MOSFET 20b. The electrode arranged in the lower portion of the MOSFET 20b functions as a drain electrode of the MOSFET 20b.

With the above-described arrangement of the MOSFETs 20a and 20b, the MOSFETs 20a and 20b line up adjacent to each other in the X-direction, for example.

The ferrite bead FB1 includes electrodes (pads) FP11 and FP12, for example. The electrode FP11 is arranged on an upper surface of the ferrite bead FB1. The electrode FP12 contacts the electrode 70 via a conductive paste or the like on a lower surface of the ferrite bead FB1. The ferrite bead FB1 is provided on a portion of the electrode 70 on the other end side in the X-direction, for example.

The ferrite bead FB2 includes electrodes (pads) FP21 and FP22, for example. The electrode FP21 is arranged on an upper surface of the ferrite bead FB2. The electrode FP22 contacts the electrode 71 via a conductive paste or the like on a lower surface of the ferrite bead FB2. The ferrite bead FB2 is provided on a portion of the electrode 71 on the one end side in the X-direction, for example.

In the above-described configurations of the ferrite beads FB1 and FB2, the ferrite beads FB1 and FB2 line up adjacent to each other in the X-direction. With the above-described arrangement of the electrodes 70 and 71, the ferrite beads FB1 and FB2 can be provided at positions close to each other in the X-direction.

In the embodiment, the ferrite beads FB1 and FB2 are provided as chips different from each other.

The support base 30 is provided on the upper surface of the substrate B. The support base 30 is provided to be sandwiched in the Y-direction between the electrodes 10a and 10b and the electrodes 70 and 71, for example. The support base 30 has a plate shape extending in the X-direction and the Y-direction. The support base 30 supports the light receiving element 40 and the light emitting element 60. An example of the support base 30 may be either a conductor or an insulator. An example of the support base 30 may be a composite material of a conductor and an insulator.

The light receiving element 40 is provided to contact an upper surface of the support base 30. The light receiving element 40 is arranged to have a light receiving surface on an upper surface of the light receiving element 40, for example.

The light receiving element 40 includes electrodes 41, 42, 43, and 44. The electrodes 41 to 44 are arranged on the upper surface of the light receiving element 40. The electrodes 41 and 43 are electrically coupled to each other in the light receiving element 40, for example, which is not illustrated in FIG. 2. The electrodes 42 and 44 are electrically coupled to each other in the light receiving element 40, for example, which is not illustrated in FIG. 2. The electrodes 41 and 43 each function as the cathode electrode of the light receiving element 40, for example. The electrodes 42 and 44 each function as an anode electrode of the light receiving element 40, for example.

The light emitting element 60 is provided above the light receiving element 40. The light emitting element 60 is arranged to have a light emission surface on a lower surface of the light emitting element 60. The emission surface of the light emitting element 60 opposes the light receiving surface of the light receiving element 40.

The light emitting element 60 includes electrodes 61 and 62. The electrodes 61 and 62 are arranged on an upper surface of the light emitting element 60. The electrode 61 functions as the anode electrode of the light emitting element 60, for example. The electrode 62 functions as the cathode electrode of the light emitting element 60, for example.

The bonding layer 50 that contacts each of the light emitting element 60 and the light receiving element 40 is provided between the light emitting element 60 and the light receiving element 40. An example of the bonding layer 50 is an insulating material having a transmission property of light to be emitted from the light emitting element 60.

Each of the terminals 80, 81, 82a, and 82b is provided such that an upper surface of the terminal contacts a lower surface of the substrate B, for example.

A signal is transmitted between the terminals 80 and 81 by equipment and a circuit not illustrated, for example. The terminal 80 is electrically coupled to the electrode 70 through a conductor (via) penetrating the substrate B, for example, which is not illustrated in FIG. 2. The terminal 81 is electrically coupled to the electrode 71 through a conductor (via) penetrating the substrate B, similarly to the terminal 80, for example, which is not illustrated in FIG. 2.

The terminals 82a and 82b are coupled to circuits or the like provided outside the semiconductor device 1. The terminal 82a is electrically coupled to the electrode arranged in the lower portion of the MOSFET 20a through the conductor (via) penetrating the substrate B, the electrode 10a, and a conductive paste, for example, which is not illustrated in FIG. 2. The terminal 82b is electrically coupled to the electrode arranged in the lower portion of the MOSFET 20b through the conductor (via) penetrating the substrate B, the electrode 10b, and a conductive paste, similarly to the terminal 82a, for example, which is not illustrated in FIG. 2.

The sealing material S is provided to cover the MOSFETs 20a and 20b, the support base 30, the light receiving element 40, the light emitting element 60, the ferrite beads FB1 and FB2, and the electrodes 10a, 10b, 70, and 71. The sealing material S can contain a non-light-transmitting material, for example.

In the above-described configuration of the semiconductor device 1, the electrodes 10a, 10b, 70, and 71, the MOSFETs 20a and 20b, and the ferrite beads FB1 and FB2 can be arranged symmetrically with respect to a YZ plane, for example.

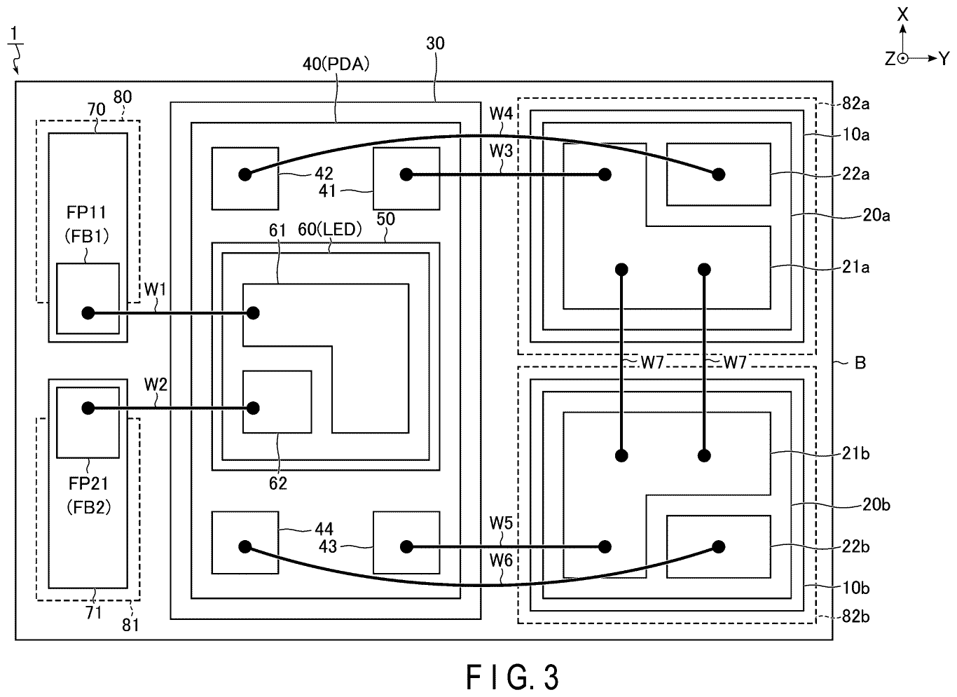

Wirings in the semiconductor device 1 will be described with reference to FIG. 3. FIG. 3 is a plan view showing an example of a planar structure of the semiconductor device according to the embodiment.

The semiconductor device 1 further includes wirings W1, W2, W3, W4, W5, W6, and W7.

An example of the wirings W1 to W7 is a wire formed by wire bonding. The wirings W1 to W7 are each composed of a conductive material.

The wiring W1 electrically couples the electrode FP11 and the electrode 61 to each other. The wiring W2 electrically couples the electrode FP21 and the electrode 62 to each other. The wiring W3 electrically couples the electrode 41 and the electrode 21a to each other. The wiring W4 electrically couples the electrode 42 and the electrode 22a to each other. The wiring W5 electrically couples the electrode 43 and the electrode 21b to each other. The wiring W6 electrically couples the electrode 44 and the electrode 22b to each other. The wiring W7 electrically couples the electrodes 21a and 21b to each other. Although an example in which the electrodes 21a and 21b are coupled to each other by two wirings W7 is illustrated in FIG. 3, the present invention is not limited to this. The electrodes 21a and 21b may be coupled to each other by one or more wirings W7.

In the above-described configuration, the wirings W1 and W2 are provided to be substantially parallel to each other in the Y-direction. With the above-described arrangement of the ferrite beads FB1 and FB2, the wirings W1 and W2 line up adjacent to each other in the X-direction.

The wirings W1 and W2 are preferably provided, respectively, at positions close to each other in the X-direction. The wiring W1 contacts the electrode FP11 on the other end side in the X-direction, for example. The wiring W2 contacts the electrode FP21 on the one end side in the X-direction, for example. Such a configuration enables the wirings W1 and W2 to be provided at positions close to each other in the X-direction.

The wiring W7 is provided to be substantially parallel to the X-direction.

With the above-described arrangement of the wirings W1, W2, and W7, the wirings W1 and W2 and the wiring W7 are arranged to be perpendicular to each other, as viewed from above.

The wirings W1 to W7 are covered with the sealing material S.

The wirings W1 to W7 can be arranged symmetrically with respect to the YZ plane, for example.

According to the embodiment, it is possible to improve a transmission characteristic and to prevent a mounting area from increasing. The improvement in the transmission characteristic and the prevention of the increase in the mounting area by the semiconductor device 1 according to the embodiment will be described below.

The semiconductor device 1 according to the embodiment includes the MOSFETs 20a and 20b, the light emitting element 60, the light receiving element 40, the ferrite bead FB1 coupled to the electrode 61 in the light emitting element 60, and the ferrite bead FB2 coupled to the electrode 62 in the light emitting element 60. Such a configuration makes it possible to prevent noise from occurring in a signal between the MOSFETs 20a and 20b without mounting a ferrite bead outside the semiconductor device 1 according to the embodiment. Therefore, it is possible to improve a transmission characteristic of the signal between the MOSFETs 20a and 20b and to prevent a mounting area from increasing.

Supplementally, in the photo relay device, a driving current of the light emitting element is supplied to the one end side from the other end side in the Y-direction with respect to the MOSFET and the light emitting element, for example. In the photo relay device, the two MOSFETs have their respective sources coupled to each other by a wiring extending in the X-direction, for example. That is, the photo relay device can be configured such that a direction in which the driving current of the light emitting element is supplied and a direction of the wiring between the sources of the two MOSFETs intersect each other. In the photo relay device having the above-described configuration, occurrence of noise in a signal and deterioration in a transmission characteristic of the signal caused thereby due to an interaction between the driving current of the light emitting element and the signal between the MOSFETs may pose a problem. Such noise occurs in a frequency band in the vicinity of 3 GHZ, for example. To prevent the occurrence of noise and the deterioration in the transmission characteristic, a filter element for reducing noise may be provided outside the photo relay device (an outside filter element may be provided). For example, outside the photo relay device, filter elements are provided on wirings coupled to the anode electrode and the cathode electrode of the light emitting element. However, in this case, there is a problem that the mounting area increases by mounting the filter elements outside the semiconductor device.

According to the embodiment, the semiconductor device 1 includes the ferrite beads FB1 and FB2 inside the semiconductor device 1. This makes it possible to prevent noise from occurring in the signal between the MOSFETs and to prevent the mounting area from increasing by the filter element outside the semiconductor device 1.

According to the embodiment, the outside filter element for reducing noise is not provided. Accordingly, a degree of freedom of the arrangement of the semiconductor device 1 can be more improved than that in a case where the outside filter element is provided.

According to the embodiment, the transmission characteristic can be more improved than that when the outside filter element is provided. More specifically, when the outside filter element is provided, the signal can interact with a current flowing through a power supply path including a wiring portion outside the semiconductor device between the filter element and the light emitting element. On the other hand, according to the embodiment, the ferrite beads FB1 and FB2 are provided in the semiconductor device 1. Accordingly, a wiring length between each of the ferrite beads FB1 and FB2 and the light emitting element 60 can be made shorter than that when the outside filter element is provided. Therefore, a transmission characteristic of the semiconductor device 1 in a high frequency band can be improved.

According to the embodiment, the wirings W1 and W2 are respectively directly coupled to the electrodes FP11 and FP12. Such a configuration makes it possible to effectively prevent the wiring length between each of the ferrite beads FB1 and FB2 and the light emitting element 60 from increasing. Such a configuration also makes it possible to improve the transmission characteristic of the semiconductor device 1 in the high frequency band.

According to the embodiment, the wirings W1 and W2 are provided to extend substantially parallel to the Y-direction. The wirings W1 and W2 line up adjacent to each other in the X-direction. In these configurations, respective magnetic fields of the wirings W1 and W2 function to cancel out each other. This makes it possible to reduce the interaction between the driving current of the light emitting element 60 and the signal. Therefore, the transmission characteristic can be improved.

In the embodiment, the ferrite bead FB1 is provided in a portion of the electrode 70 on the other end side in the X-direction. The ferrite bead FB2 is provided in a portion of the electrode 71 on the one end side in the X-direction. The wiring W1 contacts the electrode FP11 on the other end side in the X-direction. The wiring W2 contacts the electrode FP21 on the one end side in the X-direction. With these configurations, the wirings W1 and W2 are provided at positions close to each other in the X-direction. Accordingly, the wirings W1 and W2 can be provided such that the respective magnetic fields of the wirings W1 and W2 effectively cancel out each other. Therefore, the interaction between the driving current of the light emitting element 60 and the signal is reduced, whereby the transmission characteristic is improved.

### 2 Modifications

Then, semiconductor devices according to modifications will be described. Hereinafter, description of similar components to those in the embodiment will be omitted, and different components from those in the embodiment will be mainly described.

### 2.1 First Modification

Although a case where the ferrite beads FB1 and FB2 are provided as different chips has been illustrated in the above-described embodiment, the present invention is not limited to this. Ferrite beads FB1 and FB2 may be integrally provided.

Hereinafter, differences in a configuration of a semiconductor device 1 according to a first modification from that of the semiconductor device according to the embodiment will be mainly described.

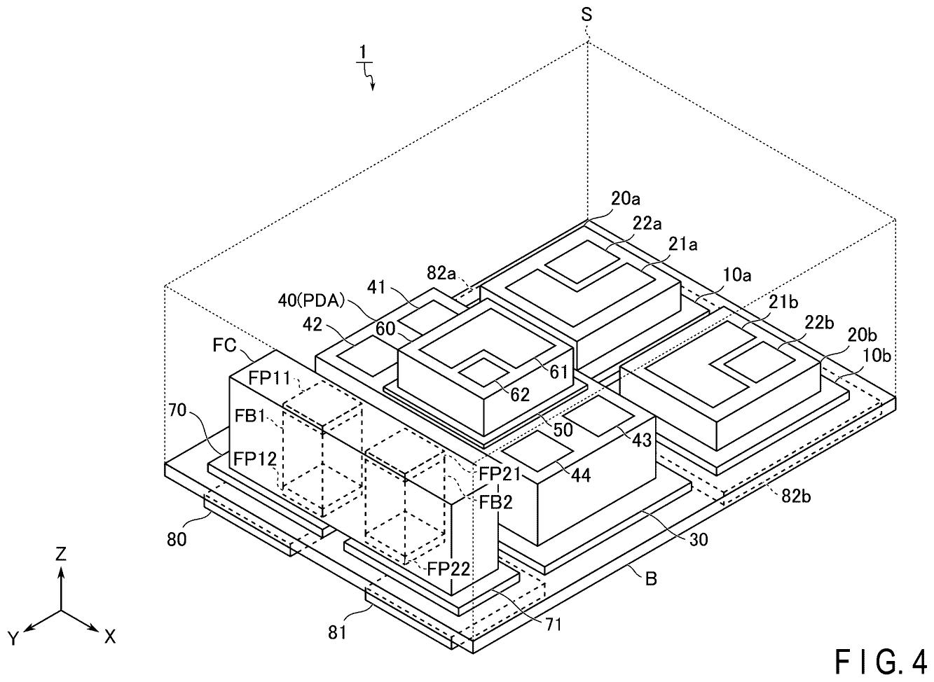

A circuit configuration of the semiconductor device 1 according to the first modification is similar to the circuit configuration in the embodiment. A structure of the semiconductor device 1 according to the first modification will be described below with reference to FIG. 4. FIG. 4 is a perspective view showing an example of the structure of the semiconductor device according to the first modification. In FIG. 4, illustration of wirings is omitted, like in FIG. 2.

The semiconductor device 1 includes a ferrite component FC. The ferrite component FC includes the ferrite beads FB1 and FB2 that are electrically insulated from each other. An electrode FP11 and an electrode FP21 are arranged to be exposed to an upper surface of the ferrite component FC, for example. An electrode FP12 and an electrode FP22 are respectively arranged to contact electrodes 70 and 71 on a lower surface of the ferrite component FC, for example.

The ferrite component FC may include the ferrite beads FB1 and FB2, and an internal configuration of the ferrite component FC is not particularly limited. For example, the ferrite component FC is a component including the ferrite beads FB1 and FB2 incorporated into a common child substrate. In this case, each of the ferrite beads FB1 and FB2 in the ferrite component FC is electrically coupled to a wire and an electrode via the child substrate corresponding to the ferrite component FC. The ferrite component FC may be a component configured as one chip including the ferrite beads FB1 and FB2 separately formed, for example. The ferrite component FC may include a configuration of a conductor (via) or the like in addition to respective configurations of the ferrite beads FB1 and FB2, which is not illustrated.

Respective configurations of a substrate B, electrodes 10a, 10b, 70, and 71, MOSFETs 20a and 20b, a support base 30, a light receiving element 40, a bonding layer 50, a light emitting element 60, terminals 80, 81, 82a, and 82b, and wirings W1 to W7 in the first modification can be similar to the configurations in the embodiment.

According to the first modification, it is also possible to improve a transmission characteristic and to prevent a mounting area from increasing, like in the embodiment.

### 2.2 Second Modification

Although a case where the electrodes FP11 and FP12 and the electrodes FP21 and FP22 are respectively provided to line up perpendicularly to the surface of the substrate B (in the Z-direction) has been illustrated in the above-described embodiment, the present invention is not limited to this. Electrodes FP11 and FP12 and electrodes FP21 and FP22 may be respectively provided to line up in the X-direction, for example.

Hereinafter, differences in a configuration of a semiconductor device 1 according to a second modification from that of the semiconductor device according to the embodiment will be mainly described.

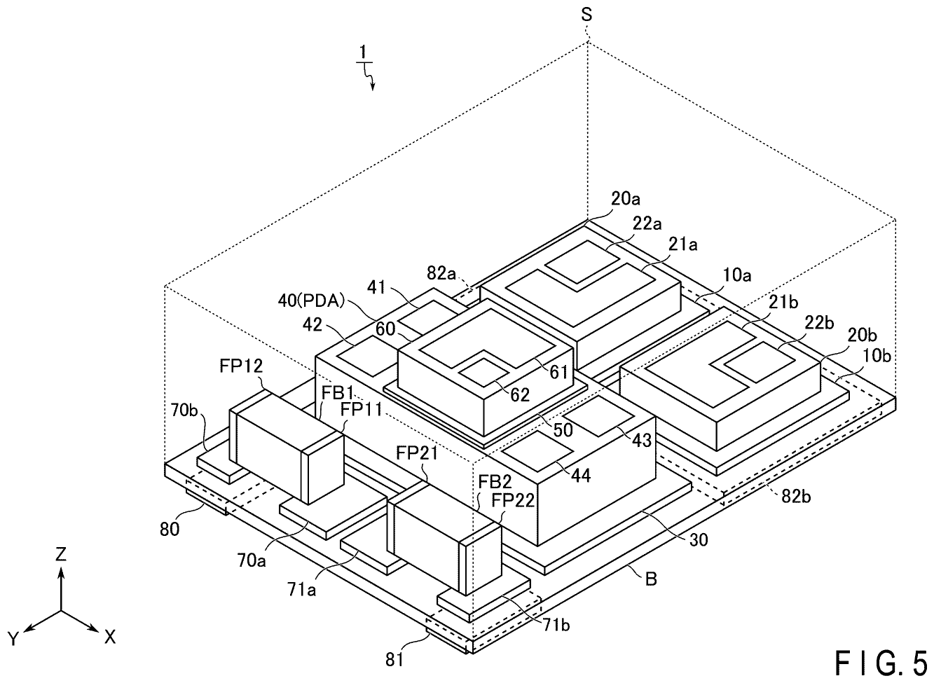

A circuit configuration of the semiconductor device 1 according to the second modification is similar to the respective circuit configurations in the embodiment and the first modification. A structure of the semiconductor device 1 according to the second modification will be described below with reference to FIG. 5. FIG. 5 is a perspective view showing an example of the structure of the semiconductor device according to the second modification. In FIG. 5, illustration of wirings is omitted, like in FIGS. 2 and 4.

The semiconductor device 1 includes electrodes 70a, 70b, 71a, and 71b instead of the electrodes 70 and 71. The electrodes 70a, 70b, 71a, and 71b are provided on an upper surface of a substrate B. An example of the electrodes 70a, 70b, 71a, and 71b is a metal foil containing copper. The electrodes 70b, 70a, 71a, and 71b are provided to line up in this order from the one end side to the other end side in the X-direction, for example. The electrodes 70a and 71a are preferably provided at positions close to each other in the X-direction.

The electrode FP11 is provided in a side surface portion of a ferrite bead FB1 on the other end side in the X-direction. The electrode FP12 is provided in a side surface portion of the ferrite bead FB1 on the one end side in the X-direction. With these configurations, the electrodes FP11 and FP12 are arranged to line up in the X-direction. The electrode FP11 is arranged such that a portion directed downward in a side surface portion of the electrode FP11 contacts the electrode 70a. The electrode FP11 is arranged to contact a portion of the electrode 70a on the one end side in the X-direction. The electrode FP12 is arranged such that a portion directed downward in a side surface portion of the electrode FP12 contacts the electrode 70b.

The electrode FP21 is provided in a portion of the ferrite bead FB2 on the one end side in the X-direction. The electrode FP22 is provided in a portion of the ferrite bead FB2 on the other end side in the X-direction. With these configurations, the electrodes FP21 and FP22 are arranged to line up in the X-direction. The electrode FP21 is arranged such that a portion directed downward in a side surface portion of the electrode FP21 contacts the electrode 71a. The electrode FP21 is arranged to contact a portion of the electrode 71a on the other end side in the X-direction. The electrode FP22 is arranged such that a portion directed downward in a side surface portion of the electrode FP22 contacts the electrode 71b.

The electrode 70b is electrically coupled to a terminal 80 through a conductor (via) penetrating the substrate B, for example, which is not illustrated in FIG. 5. The electrode 71b is electrically coupled to a terminal 81 through a conductor (via) penetrating the substrate B, for example, which is not illustrated in FIG. 2.

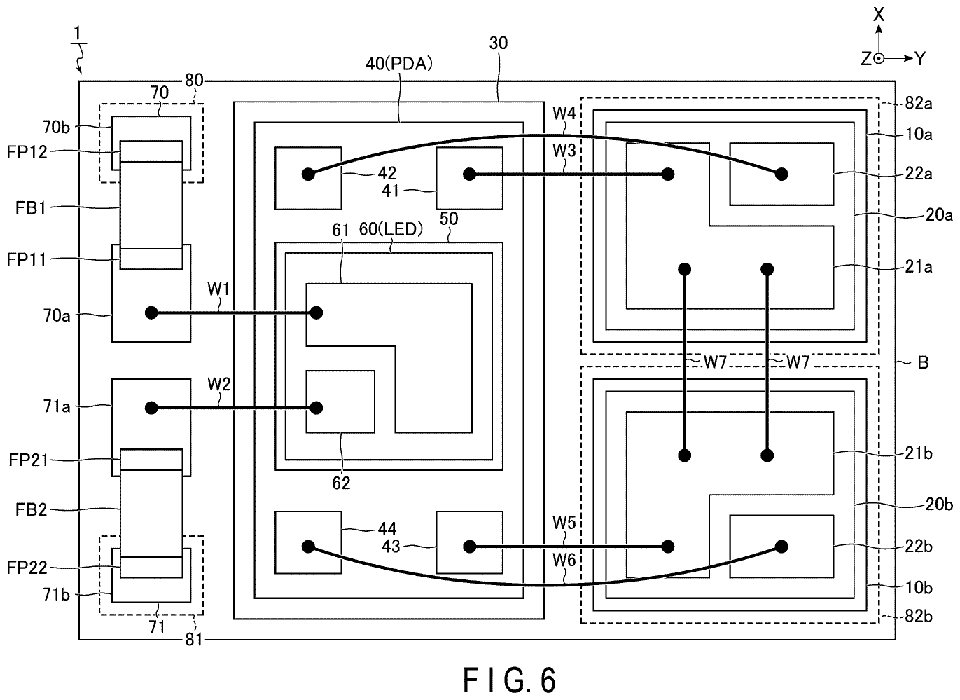

A configuration of the semiconductor device 1 will be subsequently described with reference to FIG. 6. FIG. 6 is a plan view showing an example of a planar structure of the semiconductor device according to the second modification.

The terminal 80 is provided to have a portion overlapping the electrode 70b as viewed from above, for example. As a result, the terminal 80 can be electrically coupled to the electrode 70b by a conductor. In the second modification, the terminal 80 is preferably provided not to overlap the electrode 70a as viewed from above, for example. That is, the terminal 80 is preferably arranged such that the terminal 80 and the electrode 70a are spaced apart from each other in the X-direction. In the above-described arrangement, a short circuit due to interlayer coupling between the electrode 70a and the terminal 80 occurs, for example, thereby preventing performance of the ferrite bead FB1 from deteriorating.

The terminal 81 is provided to have a portion overlapping the electrode 71b as viewed from above, for example. As a result, the terminal 81 can be electrically coupled to the electrode 71b by a conductor. In the second modification, the terminal 81 is preferably provided not to overlap the electrode 71a as viewed from above, for example. That is, the terminal 81 is preferably arranged such that the terminal 81 and the electrode 71a are spaced apart from each other in the X-direction. In the above-described arrangement, a short circuit due to interlayer coupling between the electrode 71a and the terminal 81 occurs, for example, thereby preventing performance of the ferrite bead FB2 from deteriorating.

A wiring W1 electrically couples a portion of the electrode 70a on the other end side in the X-direction and an electrode 61 to each other. A wiring W2 electrically couples a portion of the electrode 71a on the one end side in the X-direction and an electrode 62 to each other. The wirings W1 and W2 line up to be substantially parallel to the Y-direction and adjacent to each other in the X-direction, like in the embodiment and the first modification. The wirings W1 and W2 are preferably provided at positions close to each other in the X-direction, like in the embodiment and the first modification.

Respective configurations of the substrate B, electrodes 10a and 10b, MOSFETs 20a and 20b, a support base 30, a light receiving element 40, a bonding layer 50, a light emitting element 60, terminals 82a and 82b, and wirings W3 to W7 in the second modification can be similar to the configurations in the embodiment.

According to the second modification, it is also possible to improve a transmission characteristic and to prevent a mounting area from increasing, like in the embodiment and the first embodiment.

According to the second modification, the wirings W1 and W2 are respectively directly coupled to the electrodes 70a and 71a, as illustrated in FIG. 6. Such a configuration makes it easy to form the wirings W1 and W2 and to manufacture the semiconductor device 1. Therefore, according to the second modification, yield in the manufacture of the semiconductor device 1 is improved.

### 2.3 Third Modification

Although a case where the wirings W1 and W2 are respectively coupled to the electrodes 70a and 70b has been illustrated in the above-described second modification, the present invention is not limited to this. Wiring W1 and W2 may be respectively directly coupled to ferrite beads FB1 and FB2.

Hereinafter, differences in a configuration of a semiconductor device 1 according to a third modification from that of the semiconductor device according to the second modification will be mainly described.

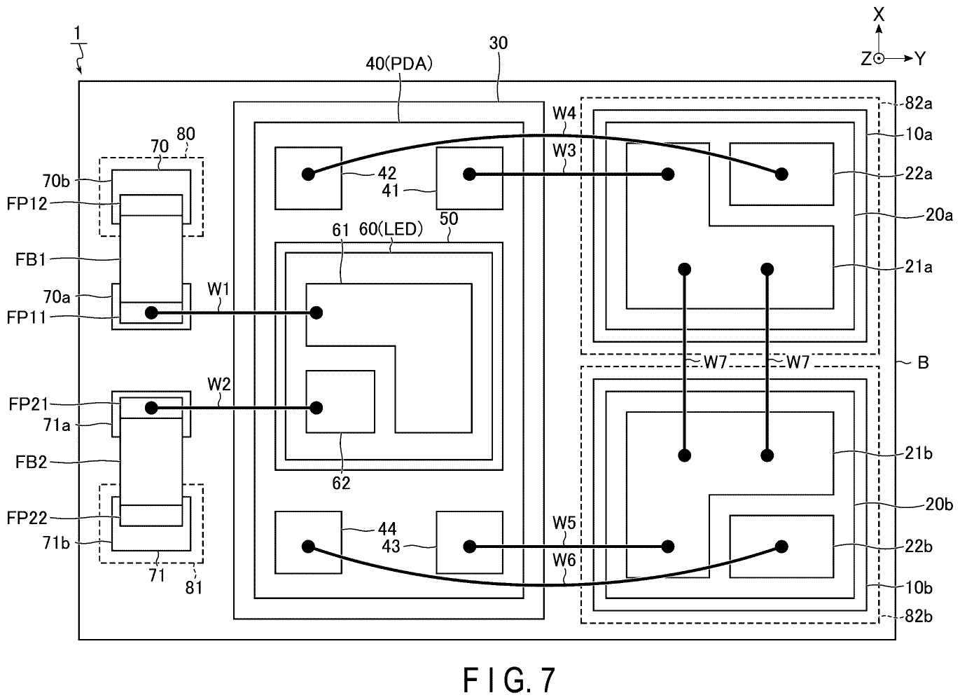

A circuit configuration of the semiconductor device 1 according to the third modification is similar to the respective circuit configurations in the embodiment, the first modification, and the second modification. A structure of the semiconductor device 1 according to the third modification will be described below with reference to FIG. 7. FIG. 7 is a plan view showing an example of a planar structure of the semiconductor device according to the third modification.

The wiring W1 is coupled to a portion directed upward in a side surface portion of an electrode FP11. The wiring W2 is coupled to a portion directed upward in a side surface portion of an electrode FP21.

In the third modification, the wirings W1 and W2 also line up substantially parallel to the Y-direction and adjacent to each other in the X-direction, like in the embodiment, the first modification, and the second modification.

The wirings W1 and W2 are preferably provided at positions close to each other in the X-direction, like in the embodiment, the first modification, and the second modification. The electrode FP11 is provided to contact a portion of an electrode 70a on the other end side in the X-direction, for example. The electrode FP21 is provided to contact a portion of an electrode 71a on the one end side in the X-direction, for example. With these configurations, the wirings W1 and W2 can be arranged at positions close to each other in the X-direction.

Respective configurations of a substrate B, electrodes 10a, 10b, 70a, and 70b, MOSFETs 20a and 20b, a support base 30, a light receiving element 40, a bonding layer 50, a light emitting element 60, terminals 80, 81, 82a, and 82b, and wirings W3 to W7 in the third modification can be similar to the configurations in the second modification.

According to the third modification, it is also possible to improve a transmission characteristic and to prevent a mounting area from increasing, like in the embodiment, the first modification, and the second modification.

### 2.4 Fourth Modification

Although a case where the electrodes FP11 and FP12 and the electrodes FP21 and FP22 respectively line up in the X direction has been illustrated in the second modification and the third modification, described above, the present invention is not limited to this. Electrodes FP11 and FP12 and electrodes FP21 and FP22 may be respectively provided to line up in the Y-direction.

Hereinafter, differences in a configuration of a semiconductor device 1 according to a fourth modification from those of the semiconductor devices according to the second modification and the third modification will be mainly described.

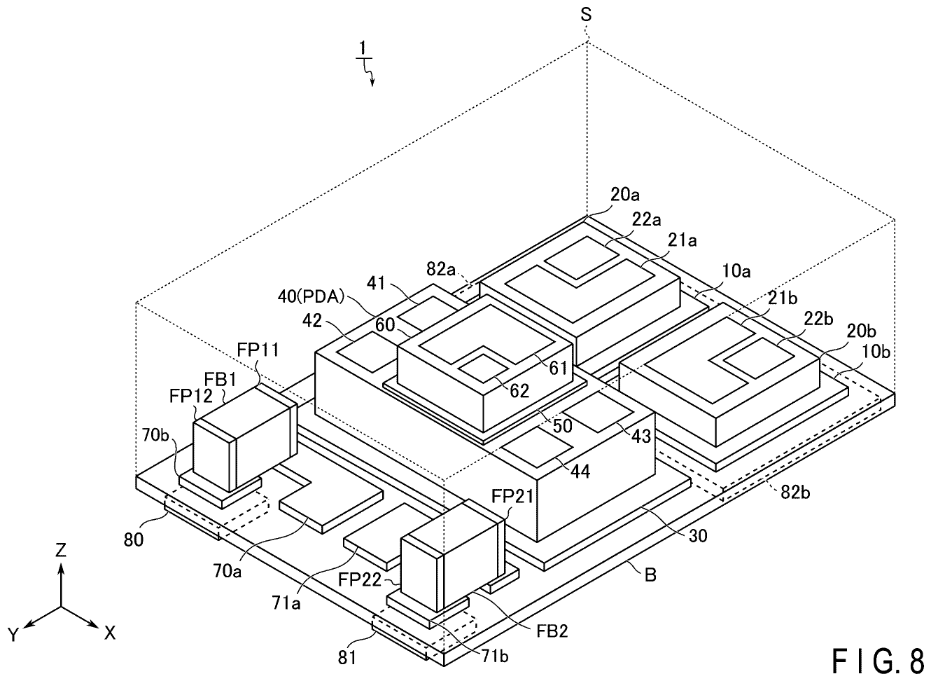

A circuit configuration of the semiconductor device 1 according to the fourth modification is similar to the respective circuit configurations in the embodiment, the first modification, the second modification, and the third modification. A structure of the semiconductor device 1 according to the fourth modification will be described below with reference to FIG. 8. FIG. 8 is a perspective view showing an example of the structure of the semiconductor device 1 according to the fourth modification. In FIG. 8, illustration of wirings is omitted, like in FIGS. 2, 4, and 5.

Electrodes 70a and 70b are provided to have portions lining up in the Y-direction. The electrode 70a is provided on the one end side in the Y-direction with respect to the electrode 70b, for example. The electrode 70a is provided to extend in the X-direction, for example. The electrode 70a includes a portion extending in the Y-direction on the other end side in the X-direction, for example. With the above-described configuration, the electrode 70a has an L shape, for example. Although an example in which the electrode 70a is provided on the one end side in the Y-direction with respect to the electrode 70b is illustrated in the foregoing description, the present invention is not limited to this. The electrode 70a may be provided on the other end side in the Y-direction with respect to the electrode 70b.

Electrodes 71a and 71b are provided to have portions lining up in the Y-direction. The electrode 71a is provided on the one end side in the Y-direction with respect to the electrode 71b, for example. The electrode 71a is provided to extend in the X-direction, for example. The electrode 71a includes a portion extending in the Y-direction on the one end side in the X-direction, for example. With the above-described configuration, the electrode 71a has an L shape, for example. Although an example in which the electrode 71a is provided on the one end side in the Y-direction with respect to the electrode 71b is illustrated in the foregoing description, the present invention is not limited to this. The electrode 71a may be provided on the other end side in the Y-direction with respect to the electrode 71b.

In the above-described configurations of the electrodes 70a and 71a, the portion extending in the Y-direction of the electrode 70a and the portion extending in the Y-direction of the electrode 71a line up adjacent to each other in the X-direction, for example. The portion extending in the Y-direction of the electrode 70a and the portion extending in the Y-direction of the electrode 71a are preferably arranged to be close to each other in the X-direction.

The electrode FP11 is provided in a side surface portion of a ferrite bead FB1 on the one end side in the Y-direction. The electrode FP12 is provided in a side surface portion of the ferrite bead FB1 on the other end side in the Y-direction. With these configurations, the electrodes FP11 and FP12 are arranged to line up in the Y-direction. The electrode FP11 is arranged such that a portion directed downward in a side surface portion of the electrode FP11 contacts the electrode 70a on the one end side in the X-direction. The electrode FP12 is arranged such that a portion directed downward in a side surface portion of the electrode FP12 contacts the electrode 70b.

The electrode FP21 is provided in a portion of a ferrite bead FB2 on the one end side in the Y-direction. The electrode FP22 is provided in a portion of the ferrite bead FB2 on the other end side in the Y-direction. With these configurations, the electrodes FP21 and FP22 are arranged to line up in the Y-direction. The electrode FP21 is arranged such that a portion directed downward in a side surface portion of the electrode FP21 contacts the electrode 71a on the other end side in the X-direction. The electrode FP22 is arranged such that a portion directed downward in a side surface portion of the electrode FP22 contacts the electrode 71b.

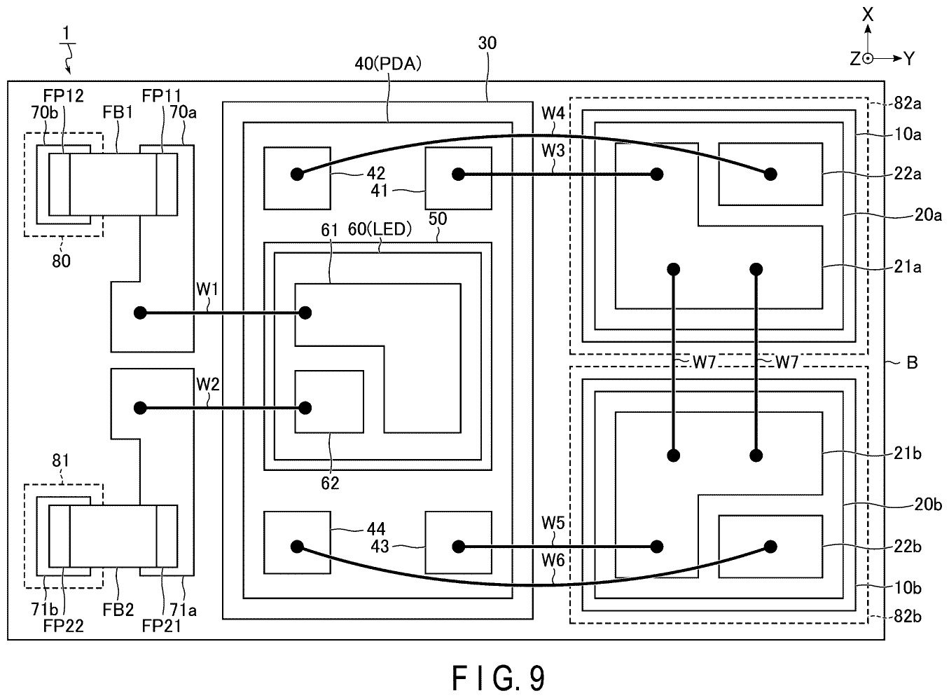

A configuration of the semiconductor device 1 will be subsequently described with reference to FIG. 9. FIG. 9 is a plan view showing an example of a planar structure of the semiconductor device according to the fourth modification.

A wiring W1 electrically couples the portion extending in the Y-direction of the electrode 70a and an electrode 61 to each other. A wiring W2 electrically couples the portion extending in the Y-direction of the electrode 71a and an electrode 62 to each other.

In the fourth modification, the wirings W1 and W2 also line up substantially parallel to the Y-direction and adjacent to each other in the X-direction, like in the embodiment, the first modification, the second modification, and the third modification. The wirings W1 and W2 are preferably provided at positions close to each other in the X-direction.

Respective configurations of a substrate B, electrodes 10a and 10b, MOSFETs 20a and 20b, a support base 30, a light receiving element 40, a bonding layer 50, a light emitting element 60, terminals 80, 81, 82a, and 82b, and wirings W3 to W7 in the fourth modification can be similar to the configurations in the second modification and the third modification.

According to the fourth modification, it is also possible to improve a transmission characteristic and to prevent a mounting area from increasing, like in the embodiment, the first modification, and the second modification.

In the fourth modification, the wirings W1 and W2 are respectively directly coupled to the electrodes 70a and 71a. This makes it easy to form the wirings W1 and W2 and to manufacture the semiconductor device 1 according to the fourth modification, like in the second modification. Therefore, yield in the manufacture of the semiconductor device 1 is improved.

### 3. Others

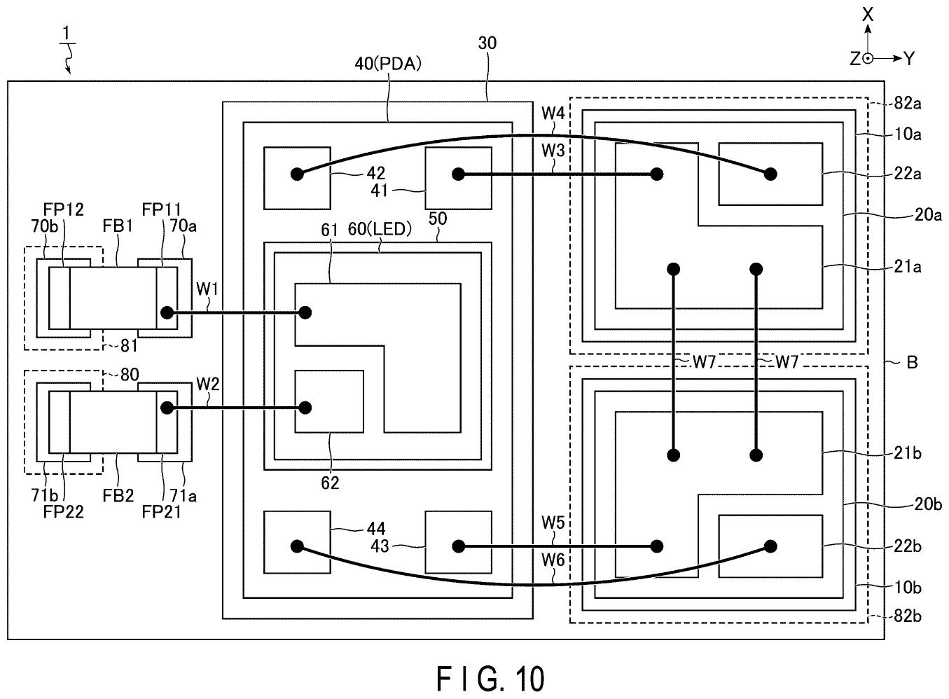

Although a case where the wirings W1 and W2 are respectively directly coupled to the electrodes 70a and 70b has been illustrated in the above-described fourth modification, the present invention is not limited to this. As illustrated in FIG. 10, wirings W1 and W2 may be respectively directly coupled to electrodes FP11 and FP21, like in the third modification. FIG. 10 is a plan view showing an example of a planar structure of a semiconductor device according to another example. In this case, ferrite beads FB1 and FB2 and electrodes 70a, 70b, 71a, and 71b are respectively arranged such that the wirings W1 and W2 are parallel to each other, for example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a first transistor and a second transistor provided above a first surface of the substrate and having their sources commonly coupled to each other;
a light emitting element provided above the first surface of the substrate and having an anode electrode and a cathode electrode;
a light receiving element provided above the first surface of the substrate and turning on or off the first transistor and the second transistor depending on a light emission state of the light emitting element;
a first filter element provided above the first surface of the substrate and coupled to the anode electrode of the light emitting element; and
a second filter element provided above the first surface of the substrate and coupled to the cathode electrode of the light emitting element.

2. The device of claim 1, further comprising
a first wiring that electrically couples the first filter element and the anode electrode of the light emitting element to each other, and
a second wiring that electrically couples the second filter element and the cathode electrode of the light emitting element to each other,
wherein the first wiring and the second wiring are arranged substantially parallel to each other as viewed from above.

3. The device of claim 2, wherein
the first filter element includes a first filter electrode and a second filter electrode, and
the second filter element includes a third filter electrode and a fourth filter electrode.

4. The device of claim 3, wherein
the first filter electrode and the second filter electrode oppose each other in a first direction perpendicular to the first surface,
the third filter electrode and the fourth filter electrode oppose each other in the first direction,
the first filter electrode is provided on an upper surface of the first filter element,
the second filter electrode is provided on a lower surface of the first filter element,
the third filter electrode is provided on an upper surface of the second filter element, and
the fourth filter electrode is provided on a lower surface of the second filter element.

5. The device of claim 3, wherein
the first filter electrode and the second filter electrode oppose each other in a first direction parallel to the first surface, and
the third filter electrode and the fourth filter electrode oppose each other in the first direction.

6. The device of claim 5, wherein
the first transistor and the second transistor line up in the first direction.

7. The device of claim 5, wherein
the first transistor and the second transistor line up in a second direction perpendicular to the first direction.

8. The device of claim 3, wherein
the first wiring is directly coupled to the first filter electrode, and
the second wiring is directly coupled to the third filter electrode.

9. The device of claim 1, wherein
the first filter element and the second filter element are integrally provided.

10. The device of claim 1, wherein
the light emitting element and the light receiving element are sandwiched in a first direction parallel to the first surface between the first filter element and the second filter element and the first transistor and the second transistor.

11. The device of claim 3, further comprising
a first terminal, a second terminal, a third terminal, and a fourth terminal that are provided below the first surface, wherein
the first terminal is coupled to the second filter electrode through a via penetrating the substrate,
the second terminal is coupled to the fourth filter electrode through a via penetrating the substrate,
the third terminal is coupled to a drain of the first transistor through a via penetrating the substrate, and
the fourth terminal is coupled to a drain of the second transistor through a via penetrating the substrate.
